(19) United States
(12) Patent Application Publication
(10) Pub. No.: US 2013/0258563 A1
(43) Pub. Date: Oct. 3, 2013

(54) DUSTPROOF AND WATERPROOF STRUCTURE AND PORTABLE ELECTRONIC DEVICE USING THE SAME

(71) Applicant: CHI MEI COMMUNICATION SYSTEMS, INC., New Taipei (TW)

(72) Inventor: JUNG-CHIEH LAI, New Taipei (TW)

(73) Assignee: CHI MEI COMMUNICATION SYSTEMS, INC., New Taipei (TW)

(21) Appl. No.: 13/746,022

(22) Filed: Jan. 21, 2013

(30) Foreign Application Priority Data
Apr. 3, 2012 (CN) 201210095703.8

(51) Int. Cl. H05K 5/06

(52) U.S. Cl. CPC H05K 5/065
USPC 361/679.01; 220/4.02

(57) ABSTRACT

A dustproof and waterproof structure used in a portable electronic device including a housing, a frame and a support plate located between the housing and the frame, the dustproof and waterproof structure includes an adhesive, a sealing element and a fastener. The adhesive attaches the frame to the support plate. The sealing element fills in gaps between the housing and the support plate. The fastener fastens the housing to the support plate and provides a resisting force causing the sealing element to be clamped between housing and the support plate.

### BACKGROUND

1. Technical Field

The disclosure generally relates to dustproof and waterproof structures used for portable electronic devices.

2. Description of the Related Art

Portable electronic devices, such as mobile phones, personal digital assistants (PDAs), are now in widespread use. During normal use, dust and water may be easily penetrate into the portable electronic device. Therefore, portable electronic devices include dustproof and waterproof structures. Generally, the dustproof and waterproof structures need fasteners for mounting on the portable electronic device. The fasteners occupy a large space of the portable electronic devices, and also increase size of the portable electronic devices.

Therefore, there is room for improvement within the art.

### BRIEF DESCRIPTION OF THE DRAWINGS

Many aspects of an exemplary dustproof and waterproof structure can be better understood with reference to the following drawings. The components in the drawings are not necessarily drawn to scale, the emphasis instead being placed upon clearly illustrating the principles of the exemplary dustproof and waterproof structure. Moreover, in the drawings, like reference numerals designate corresponding parts throughout the several views. Wherever possible, the same reference numbers are used throughout the drawings to refer to the same or like elements of an embodiment.

FIG. 1 is a schematic view of a portable electronic device using a dustproof and waterproof structure, according to an exemplary embodiment.

FIG. 2 is an exploded view of the portable electronic device shown in FIG. 1.

FIG. 3 is similar to FIG. 2, but shown from another angle.

FIG. 4 is an exploded view of a display assembly shown in FIG. 2.

FIG. 5 is similar to FIG. 4, but shown from another angle.

FIG. 6 is a cross sectional view of the portable electronic device shown of FIG. 1 taken along line VI-VI.

### DETAILED DESCRIPTION

Reference is now made to the drawings to describe various exemplary embodiments of the present disclosure in detail.

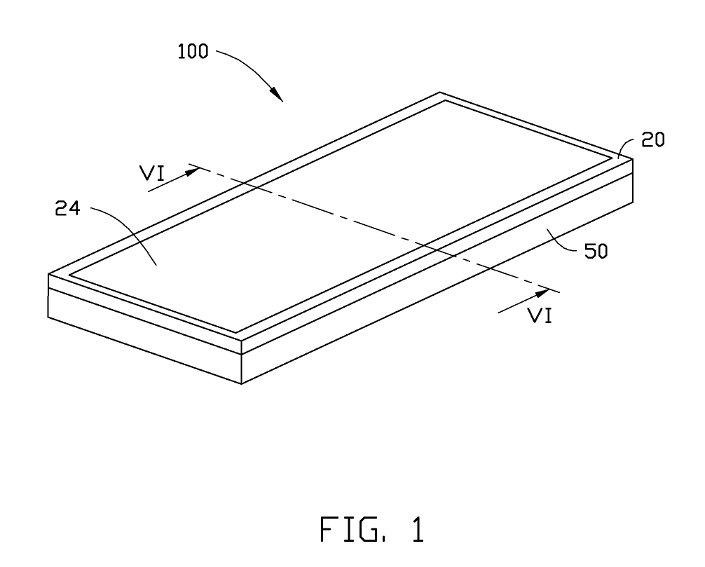

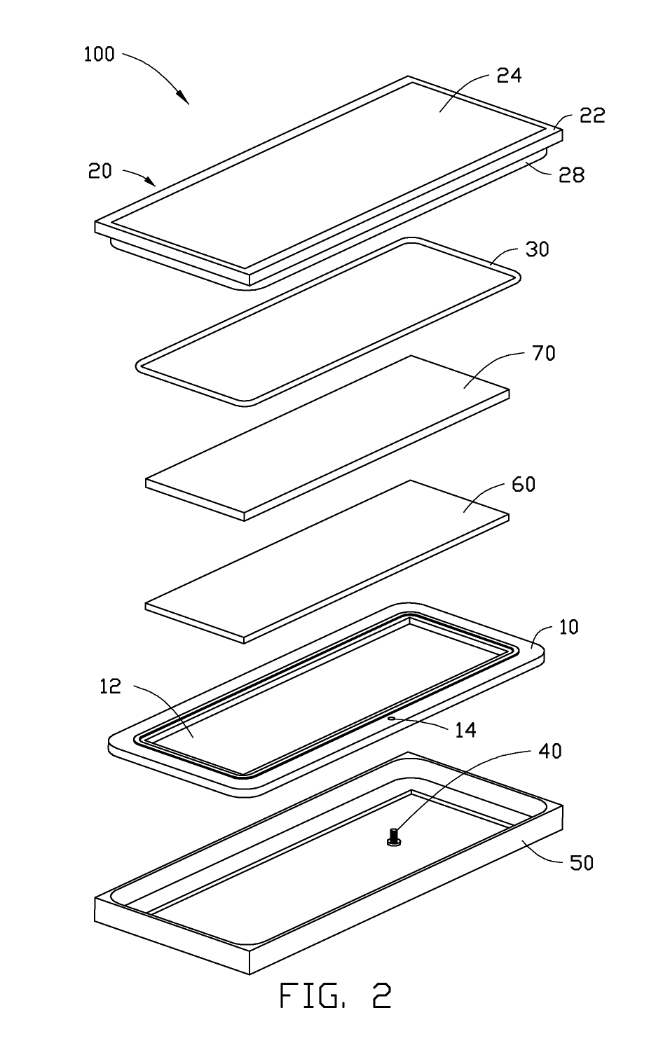

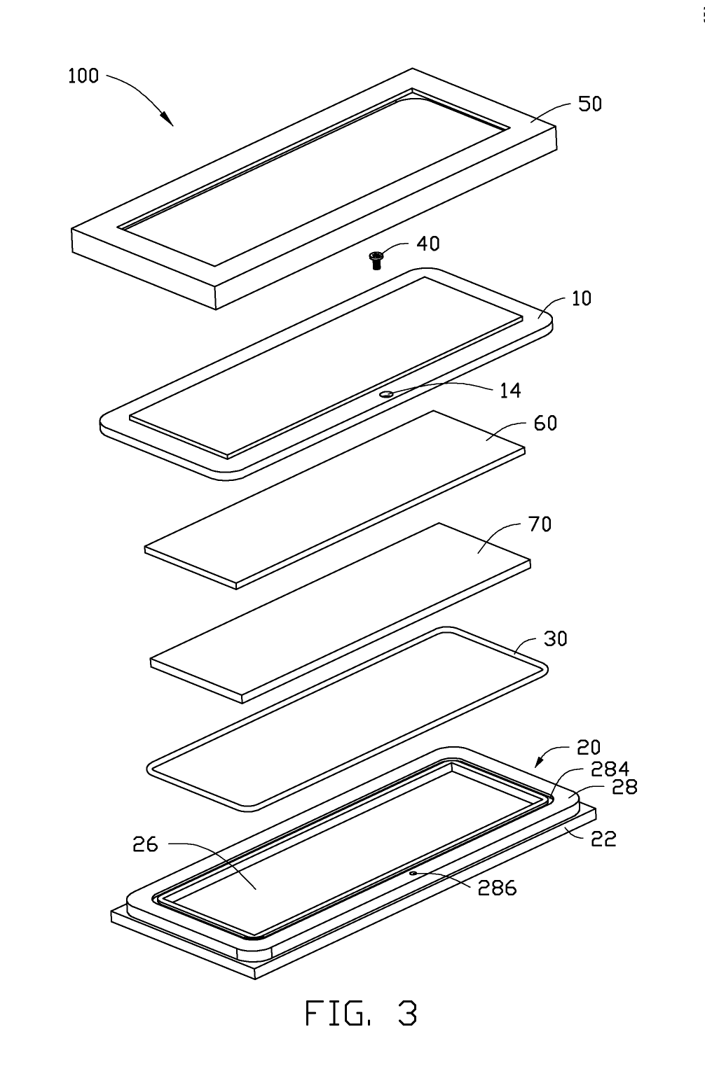

FIGS. 1 to 3 is a portable electronic device 100 according to an exemplary embodiment of the present disclosure. The portable electronic device 100 includes a housing 10, a display assembly 20, and a sealing element 30, a fastener 40 and a cover 50. The housing 10 is received in the cover 50. The sealing element 30 is sandwiched between the housing 10 and the display assembly 20. The fastener 40 is configured for fixing the display assembly 20 on the housing 10. In this embodiment, the fastener 40 is a screw. In this embodiment, the sealing element 30 is made of elastic material, such as rubber.

The housing 10 defines an recessed portion 12 and a through hole 14 adjacent to the recessed portion 12. A battery 60 is received in the recessed portion 12, and a circuit board 70 is located above the battery 60.

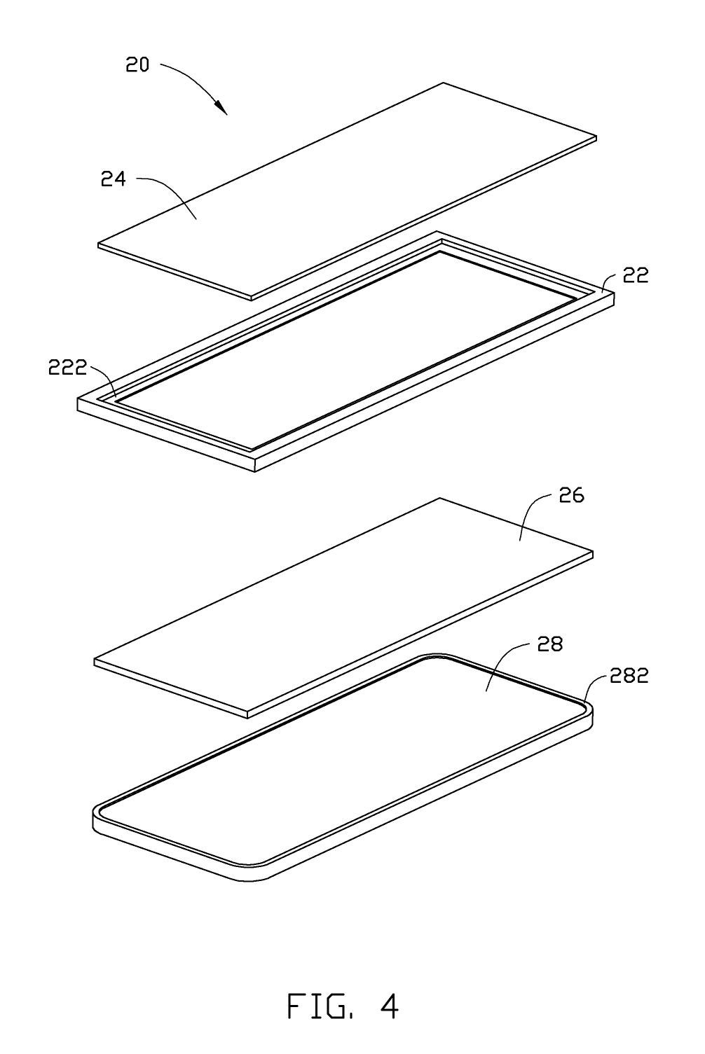

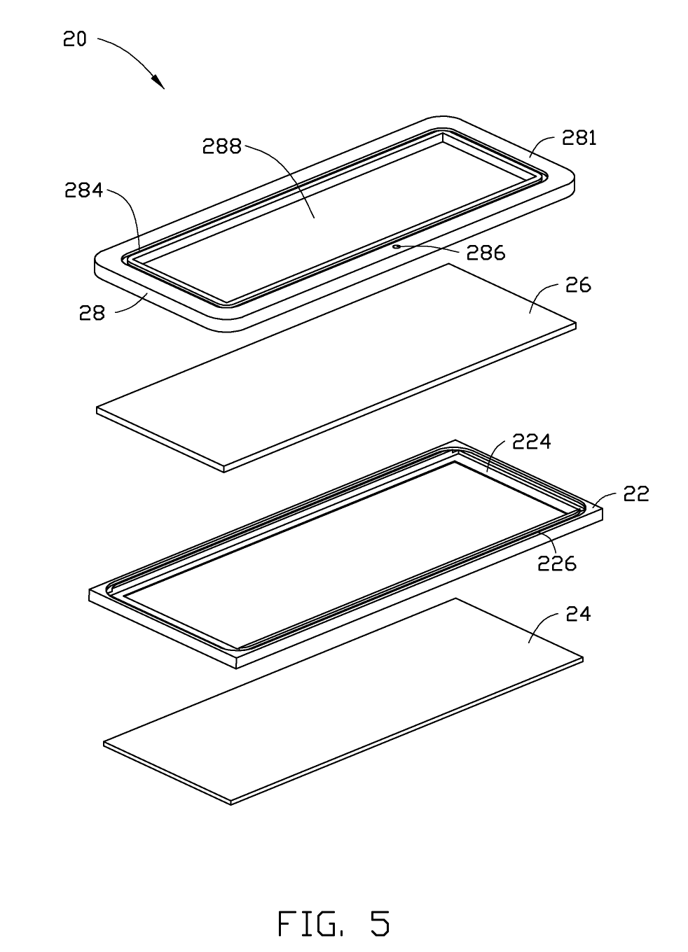

FIG. 4 and FIG. 5 show that the display assembly 20 includes a frame 22, a touch panel 24, a display screen 26 opposite to the touch panel 24 and a support plate 28. The touch panel 24 and the display screen 26 are received in the frame 22. The support plate 28 is fixed to the frame 22.

The frame 22 defines a first receiving groove 222 and a second receiving groove 224 communicating with the first receiving groove 222. The touch panel 24 is received in the first receiving groove 222, and the display screen 26 is received in the second receiving groove 224. The frame 22 also defines a peripheral slot 226 around the second receiving groove 224.

The support plate 28 includes a peripheral flange 281. An extending wall 282, narrower than the peripheral flange 281, extends perpendicularly from a first side of the peripheral flange 281. The peripheral flange 281 defines a peripheral groove 284 and a mounting hole 286 at a second side of the peripheral flange 281 opposite to the first side. The extending wall 282 is received in the peripheral slot 226 to fill gaps between the frame 22 and the support plate 28. The peripheral groove 284 receives the sealing element 30, and the sealing element 30 is latched between the housing 10 and the support plate 28 to fill gaps between the housing 10 and the support plate 28. The support plate 28 further defines a cutout 288 corresponding to the recessed portion 12. The extending wall 282 and the peripheral groove 284 surround the cutout 288. The mounting hole 286 adjacent to the peripheral groove 284 is defined on the second side of peripheral flange 281.

The fastener 40 extends through the through hole 14 and is engaged with the mounting hole 286. The housing 10 and the support plate 28 are fastened by the fastener 40. The fastener 40 provides a resisting force causing the sealing element 30 to be tightly clamped between housing 10 and the support plate 28.

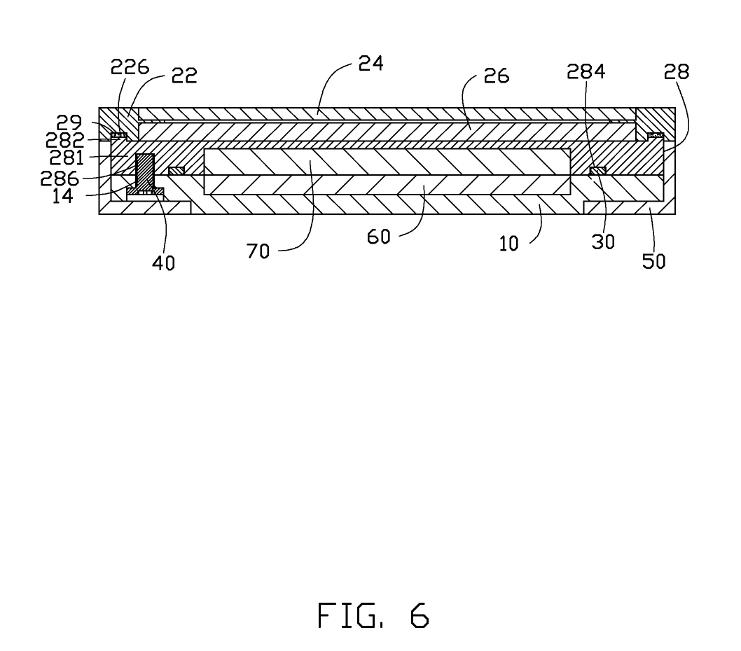

FIG. 6 shows that the portable electronic device 100 is assembled as follows:

The touch panel 24 is secured in the first receiving groove 222. In addition, the display screen 26 is secured in the second receiving groove 224. In this embodiment, the touch panel 24 and the display screen 26 are secured by adhesive. An adhesive is filled in the peripheral slot 226, and the extending wall 282 is pressed into the peripheral slot 226. A solid sealant 29 is formed between the extending wall 282 and the peripheral slot 226 after the adhesive has dried.

The sealing element 30 is partially received in the peripheral groove 284. The battery 60 and the circuit board 70 are mounted in the recessed portion 12 and the cutout 288. The sealing element 30 is pressed by the housing 10, and the through hole 14 is aligned with the mounting hole 286. The fastener 40 passes through the through hole 14 and is engaged in the mounting hole 286 causing the sealing element 30 to be tightly clamped between housing 10 and the support plate 28. The cover 50 receives the housing 10 and the support plate 28, and the assembly process of the portable electronic device 100 is completed.

The extending wall 282 is received in the peripheral slot 226 to fill the gaps between the frame 22 and the support plate 28, and the sealing element 30 fills the gaps between the housing 10 and the support plate 28 to prevent dust and water from entering into the portable electronic device 100. The fastener 40 is mounted on the housing 10 and the support plate 28, and does not take up a display surface area of the frame 22.

In an alternative exemplary embodiment, the frame 22 includes the extending wall 282, and the support plate 28 defines the peripheral slot 226.

In an alternative exemplary embodiment, the housing 10 defines the peripheral groove 284.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in matters of shape, size, and arrangement of parts within the principles of exemplary disclosure to the full extent indicated by the broad general meaning of the terms in which the appended claims are expressed.

What is claimed is:

1. A dustproof and waterproof structure used in a portable electronic device comprising a housing, a frame and a support plate located between the housing and the frame, the dustproof and waterproof structure comprising:
an adhesive attaching the frame to the support plate;
a sealing element filling in gaps between the housing and the support plate; and
a fastener;
wherein the fastener fastens the housing to the support plate and provides a resisting force causing the sealing element to be clamped between housing and the support plate.

2. The dustproof and waterproof structure as claimed in claim 1, wherein one of the frame and the support plate defines a peripheral slot, and the other one of the frame and the support plate includes an extending wall, the extending wall is received in the peripheral slot.

3. The dustproof and waterproof structure as claimed in claim 2, wherein the adhesive is received in the peripheral slot and is resisted by the extending wall.

4. The dustproof and waterproof structure as claimed in claim 3, wherein one of the housing and the support plate defines a peripheral groove, the sealing element is received in the peripheral groove.

5. The dustproof and waterproof structure as claimed in claim 4, wherein the support plate includes a peripheral flange, the extending wall extends perpendicularly from a first side of the peripheral flange; the peripheral flange defines the peripheral groove and a mounting hole at a second side of the peripheral flange opposite to the first side.

6. The dustproof and waterproof structure as claimed in claim 1, wherein the housing defines a through hole, and the support plate defines a mounting hole; the fastener passes through the through hole and is engaged with the mounting hole to fasten the housing to the support plate.

7. The dustproof and waterproof structure as claimed in claim 6, wherein the fastener is a screw.

8. The dustproof and waterproof structure as claimed in claim 1, wherein the sealing element is made of elastic material.

9. A portable electronic device, comprising:
a housing;
a frame;
a support plate located between the housing and the frame; and
a dustproof and waterproof structure comprising:
an adhesive attaching the frame to the support plate;
a sealing element filling in gaps between the housing and the support plate; and a fastener;
wherein the fastener fastens the housing to the support plate and provides a resisting force causing the sealing element to be clamped between housing and the support plate.

10. The portable electronic device as claimed in claim 9, wherein a display screen is received in the frame; one of the frame and the support plate defines a peripheral slot, and the other one of the frame and the support plate includes an extending wall, the extending wall is received in the peripheral slot.

11. The portable electronic device as claimed in claim 10, wherein the adhesive is received in the peripheral slot and is resisted by the extending wall.

12. The portable electronic device as claimed in claim 11, wherein one of the housing and the support plate defines a peripheral groove, the sealing element is received in the peripheral groove.

13. The portable electronic device as claimed in claim 12, wherein the support plate includes a peripheral flange, the extending wall extends perpendicularly from a first side of the peripheral flange; the peripheral flange defines the peripheral groove and a mounting hole at a second side of the peripheral flange opposite to the first side.

14. The portable electronic device as claimed in claim 9, wherein the housing defines a through hole, and the support plate defines a mounting hole; the fastener passes through the through hole and is engaged with the mounting hole to fasten the housing to the support plate.

15. The portable electronic device as claimed in claim 14, wherein the fastener is a screw.

16. The portable electronic device as claimed in claim 9, wherein the sealing element is made of elastic material.

17. The portable electronic device as claimed in claim 9, further comprising a cover, wherein the housing is received in the cover.
